(19) United States
(12) Patent Application Publication
(10) Pub. No.: US 2025/0241000 A1
(43) Pub. Date: Jul. 24, 2025

(54) HIGH-VOLTAGE SEMICONDUCTOR DEVICE

(71) Applicant: Vanguard International Semiconductor Corporation, Hsinchu (TW)

(72) Inventors: Cheng-Tsung Wu, Taipei City (TW); Yu-Sheng Chiu, New Taipei City (TW)

(73) Assignee: Vanguard International Semiconductor Corporation, Hsinchu (TW)

(21) Appl. No.: 18/421,956

(22) Filed: Jan. 24, 2024

(51) Int. Cl. H01L 29/78; H01L 23/528; H01L 29/06; H01L 29/40

(52) U.S. Cl. CPC H10D 30/603; H01L 23/528; H10D 62/10; H10D 64/111

(57) ABSTRACT

A high-voltage semiconductor device includes a substrate having a first conductivity type. A first well region having the first conductivity type is disposed in the substrate. A second well region having a second conductivity type is disposed in the substrate. A first doped top layer having the first conductivity type is disposed between the first well region and the second well region. A drain contact region is disposed in the first well region. A source contact region is disposed in the second well region. An isolation region is disposed on the first doped top layer. A gate electrode is disposed on the isolation region and extended laterally onto the second well region. A field plate is disposed on the isolation region and extended laterally onto the first well region.

### BACKGROUND OF THE INVENTION

### 1. Field of the Invention

The present disclosure relates generally to semiconductor technology, and more particularly to high-voltage semiconductor devices including ultra-high-voltage p-type metal-oxide-semiconductor field-effect-transistors.

### 2. Description of the Prior Art

Metal-oxide-semiconductor field-effect-transistor (MOSFETs) are common components used in integrated circuits, and usually used as power switching components in various power applications and power supply lines. For example, in a bridge circuit where switching components are connected in series, MOSFETs are used as switching components and disposed in a high-side circuit and a low-side circuit respectively. The high-side MOSFET and the low-side MOSFET are turned on and turned off alternately. In order to prevent the high-side MOSFET and the low-side MOSFET from being turned on at the same time to cause shoot-through, an anti-shoot-through protection device is provided to detect the highest potential signal of the high-side circuit and then transmit this highest potential signal back to the low-side circuit. When the highest potential signal of the high-side circuit is detected to have a malfunction, the low-side circuit transmits a signal to shut down the high-side circuit. In the current bridge circuit, an n-type MOSFET is usually used to transmit a signal from the low-side circuit to the high-side circuit, but no device is provided to transmit a signal from the high-side circuit to the low-side circuit.

### SUMMARY OF THE INVENTION

In view of this, the present disclosure provides high-voltage semiconductor devices including an ultra-high-voltage p-type metal-oxide-semiconductor (PMOS) field-effect-transistor (FET). The high-voltage semiconductor devices withstand ultra-high voltages of more than negative 700V and may be fabricated by using the process flow of an n-type MOSFET without additional photomask, thereby saving the manufacturing cost. Moreover, the high-voltage semiconductor devices maintain a smaller chip area.

According to an embodiment of the present disclosure, a high-voltage semiconductor device is provided and includes a substrate, a first well region, a second well region, a first doped top layer, a drain contact region, a source contact region, an isolation region, a gate electrode and a field plate. The substrate has a first conductivity type. The first well region has the first conductivity type and is disposed in the substrate. The second well region has a second conductivity type and is disposed in the substrate. The first doped top layer has the first conductivity type and is disposed between the first well region and the second well region. The drain contact region is disposed in the first well region. The source contact region is disposed in the second well region. The isolation region is disposed on the first doped top layer. The gate electrode is disposed on the isolation region and extended laterally onto the second well region. In addition, the field plate is disposed on the isolation region and extended laterally onto the first well region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a high-voltage semiconductor device according to an embodiment of the present disclosure.

FIG. 2 is a schematic cross-sectional view of a high-voltage semiconductor device according to another embodiment of the present disclosure.

FIG. 3 shows characteristics of drain current, transconductance and gate voltage of a high-voltage semiconductor device according to an embodiment of the present disclosure.

FIG. 4 shows characteristics of drain current and drain voltage of a high-voltage semiconductor device under different gate voltages according to an embodiment of the present disclosure.

FIG. 5 shows characteristics of drain current and gate-to-source voltage difference of two high-voltage semiconductor devices according to some embodiments of the present disclosure.

FIG. 6, FIG. 7, FIG. 8 and FIG. 9 are schematic cross-sectional views of some stages of a method of fabricating a high-voltage semiconductor device according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to high-voltage semiconductor devices including ultra-high-voltage (UHV) p-type metal-oxide-semiconductor (PMOS) field-effect-transistors (FETs). In the high-voltage semiconductor devices, a p-type doped top layer and a p-type well region of a source region in an n-type MOSFET structure are used to be a drain region of a p-type MOSFET of the high-voltage semiconductor devices, thereby withstanding ultra-high voltages of more than negative 700V. Therefore, the high-voltage semiconductor devices are suitable for various applications under ultra-high operating voltages. Moreover, the fabrication of the high-voltage semiconductor devices is compatible with the process flow of fabricating an n-type MOSFET without additional photomask, thereby saving the manufacturing cost of the high-voltage semiconductor devices and maintaining a smaller chip area.

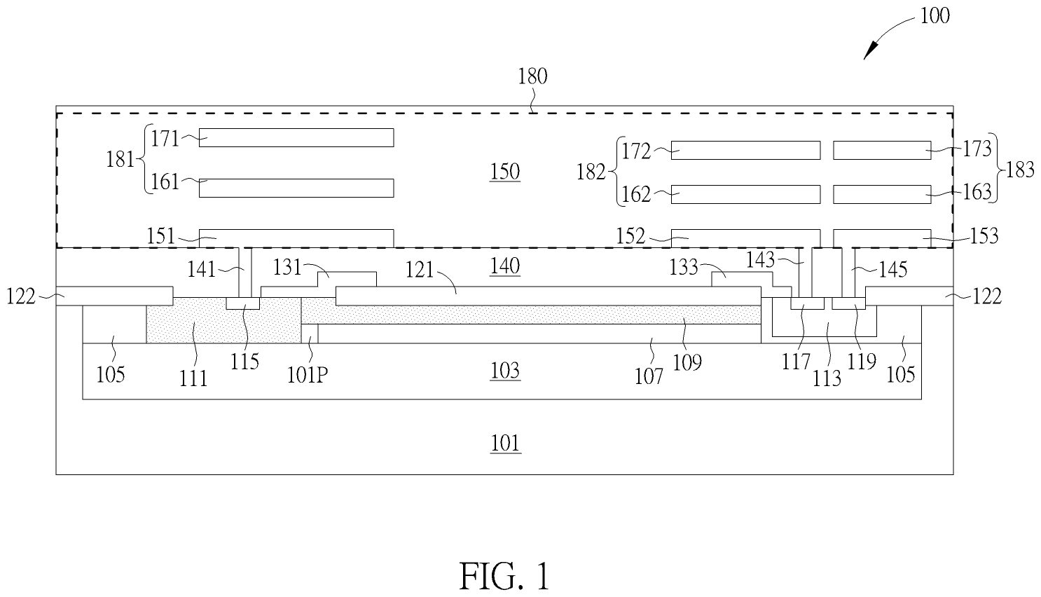

FIG. 1 is a schematic cross-sectional view of a high-voltage semiconductor device 100 according to an embodiment of the present disclosure. The high-voltage semiconductor device 100 includes a substrate 101 having a first conductivity type, such as a p-type semiconductor substrate. The composition of the substrate 101 may include silicon (Si), silicon carbide (SiC), aluminum nitride (AlN), gallium nitride (GaN) or other suitable semiconductor materials. A first well region 111 having the first conductivity type, such as a p-type well (PW), is disposed in the substrate 101. A second well region 113 having a second conductivity type, such as an n-type well (NW) is also disposed in the substrate 101. In addition, a first doped top layer 109 having the first conductivity type, such as a p-type doped top layer (PTOP), is disposed between the first well region 111 and the second well region 113. In this embodiment, one side (for example, the left side) of the first doped top layer 109 is in contact with the side surface of the first well region 111, so that the first well region 111 and the first doped top layer 109 construct a continuous structure having the first conductivity type (for example, p-type) that is used as a drain region of a PMOS FET of the high-voltage semiconductor device 100, thereby achieving the effect of withstanding ultra-high voltages. In some embodiments, the doping concentration of the first well region 111 may be higher than the doping concentration of the first doped top layer 109, which helps carriers flow from the first well region 111 to the first doped top layer 109, thereby reducing the on-state resistance (Ron) of the high-voltage semiconductor device 100.

In one embodiment, the high-voltage semiconductor device 100 optionally includes a second doped top layer 107 having the second conductivity type, such as an n-type doped top layer (NTOP), disposed directly below the first doped top layer 109 and located between the first well region 111 and the second well region 113. In this embodiment, the second doped top layer 107 is laterally separated from the first well region 111, and a portion 101P of the substrate is located between the first well region 111 and the second doped top layer 107. In some embodiments, the top surface of the second doped top layer 107 is in direct contact with the bottom surface of the first doped top layer 109, and the doping concentration of the second doped top layer 107 is substantially the same as the doping concentration of the first doped top layer 109. Therefore, the surface electric field is reduced to improve the breakdown voltage of the high-voltage semiconductor device 100, which is beneficial to ultra-high voltage applications.

Still referring to FIG. 1, the high-voltage semiconductor device 100 further includes a deep well region 103 having the second conductivity type, such as a deep high voltage n-well (DHVNW). The deep well region 103 is disposed in the substrate 101 and located directly below the first well region 111, the second doped top layer 107 and the second well region 113. In some embodiments, the bottom surface of the first well region 111 is in direct contact with the top surface of the deep well region 103, and the bottom surface of the second doped top layer 107 is also in direct contact with the top surface of the deep well region 103. The deep well region 103 and the second doped top layer 107 isolate both the first doped top layer 109 and the first well region 111 from the substrate 101, thereby avoiding a current punch-through in the first well region 111 and the first doped top layer 109, and further improving the breakdown voltage of the high-voltage semiconductor device 100. In addition, a third well region 105 having the second conductivity type, such as a high voltage n-well (HVNW), is disposed on the deep well region 103 and surrounds the first well region 111, the first doped top layer 109, the second doped top layer 107 and the second well region 113. The combination of the third well region 105 and the deep well region 103 helps to isolate both the first doped top layer 109 and the first well region 111 from the substrate 101, thereby further avoiding the current punch-through and enhancing the breakdown voltage of the high-voltage semiconductor device 100. In some embodiments, the doping concentration of the third well region 105 is substantially the same as the doping concentration of the deep well region 103, and the doping concentrations of both the third well region 105 and the deep well region 103 may be lower than the doping concentrations of both the second doped top layer 107 and the first doped top layer 109. In one embodiment, one side (for example, the right side) of the second doped top layer 107 and one side (for example, the right side) of the first doped top layer 109 may be vertically aligned with each other. A portion of the third well region 105 is located between the second well region 113 and the aforementioned side (for example, the right side) of the first doped top layer 109. The portion of the third well region 105 is also located between the second well region 113 and the aforementioned side (for example, the right side) of the second doped top layer 107. The first doped top layer 109 and the second doped top layer 107 both are laterally separated from the second well region 113.

In addition, the high-voltage semiconductor device 100 includes a drain contact region 115 disposed in the first well region 111 and a source contact region 117 disposed in the second well region 113. Both the drain contact region 115 and the source contact region 117 have the first conductivity type, such as p-type heavily doped regions (P⁺). Moreover, a bulk contact region 119 is disposed in the second well region 113. The bulk contact region 119 has the second conductivity type, such as an n-type heavily doped region (N⁺), and is laterally separated from the source contact region 117. The second well region 113 may be used as a source region of the high-voltage semiconductor device 100. The second well region 113 is located in the third well region 105, and the doping concentration of the second well region 113 is higher than the doping concentration of the third well region 105.

Still referring to FIG. 1, the high-voltage semiconductor device 100 further includes an isolation region 121 disposed on the first doped top layer 109. A gate electrode 133 is disposed on the isolation region 121 and extended laterally onto the second well region 113. A field plate 131 is also disposed on the isolation region 121 and extended laterally onto the first well region 111. In addition, another isolation region 122 is disposed on the third well region 105. When viewed from top, the isolation region 122 surrounds the first well region 111 and the second well region 113 to electrically isolate the high-voltage semiconductor device 100 from adjacent components. In some embodiments, the isolation regions 121 and 122 may be field oxide layers (FOX) or shallow trench isolation structures (STI). Moreover, the field plate 131 and the gate electrode 133 may have the same composition, such as polysilicon. In some embodiments, the field plate 131 and the gate electrode 133 may be formed from two laterally separated portions of the same polysilicon layer.

In addition, the high-voltage semiconductor device 100 includes a drain electrode 151 that is electrically connected to the drain contact region 115 through a drain contact 141. A source electrode 152 is electrically connected to the source contact region 117 through a source contact 143. A bulk electrode 153 is electrically connected to the bulk contact region 119 through a bulk contact 145. The drain contact 141, the source contact 143 and the bulk contact 145 may be contact plugs formed in an interlayer dielectric (ILD) layer 140. The drain electrode 151, the source electrode 152 and the bulk electrode 153 may be conductive portions formed on the ILD layer 140 and laterally separated from each other. In one embodiment, the drain electrode 151, the source electrode 152 and the bulk electrode 153 may be formed from different portions of a first metal layer. Moreover, the high-voltage semiconductor device 100 further includes an interconnect structure 180 disposed above the drain electrode 151, the source electrode 152 and the bulk electrode 153. The interconnect structure 180 includes multiple metal layers and multiple inter-metal dielectric (IMD) layers 150 stacked alternately. These metal layers may include a first portion 181, a second portion 182 and a third portion 183 laterally separated from each other and electrically connected to the drain electrode 151, the source electrode 152 and the bulk electrode 153, respectively, through multiple vias (not shown) formed in the IMD layers 150. The first portion 181 includes multiple drain field plates 161 and 171. The second portion 182 includes multiple source field plates 162 and 172. The third portion 183 includes multiple bulk wires 163 and 173. Each of the vertical projection areas of the drain field plates 161 and 171 covers and is larger than the vertical projection area of the field plate 131. In one embodiment, as shown in FIG. 1, two sides of the drain field plate 161 and two sides of the drain field plate 171 are vertically aligned with two sides of the drain electrode 151. In another embodiment, the vertical projection area of the drain field plate 171 may be larger than the vertical projection area of the drain field plate 161, and the vertical projection area of the drain field plate 161 may be larger than the vertical projection area of the drain electrode 151. Moreover, each of the vertical projection areas of the source field plates 162 and 172 covers and is larger than the vertical projection area of the gate electrode 133. In one embodiment, as shown in FIG. 1, two sides of the source field plate 162 and two sides of the source field plate 172 are vertically aligned with two sides of the source electrode 143. In another embodiment, the vertical projection area of the source field plate 172 may be larger than the vertical projection area of the source field plate 162, and the vertical projection area of the source field plate 162 may be larger than the vertical projection area of the source electrode 152. Furthermore, the drain field plate 161, the source field plate 162 and the bulk wire 163 may be formed from different portions of a second metal layer. The drain field plate 171, the source field plate 172 and the bulk wire 173 may be formed from different portions of a third metal layer.

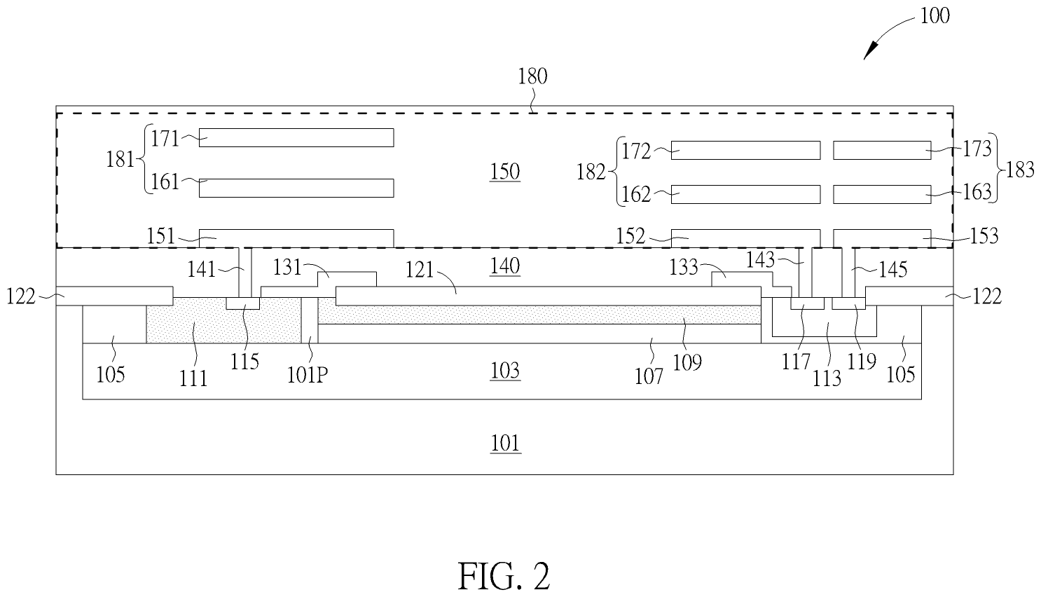

FIG. 2 is a schematic cross-sectional view of a high-voltage semiconductor device 100 according to another embodiment of the present disclosure. In the high-voltage semiconductor device 100 of FIG. 2, one side (for example, the left side) of the second doped top layer 107 is vertically aligned with one side (for example, the left side) of the first doped top layer 109. A portion 101P of the substrate is located between the first well region 111 and the aforementioned side (for example, the left side) of the first doped top layer 109. The portion 101P of the substrate is also located between the first well region 111 and the aforementioned side (for example, the left side) of the second doped top layer 107. In this embodiment, the first well region 111, the portion 101P of the substrate and the first doped top layer 109 construct a continuous structure having the first conductivity type (for example, p-type) to be used as a drain region of a PMOS FET of the high-voltage semiconductor device 100, thereby achieving the effect of withstanding ultra-high voltages. The other features of the high-voltage semiconductor device 100 of FIG. 2 may refer to the aforementioned description of the high-voltage semiconductor device 100 of FIG. 1, and are not repeated herein.

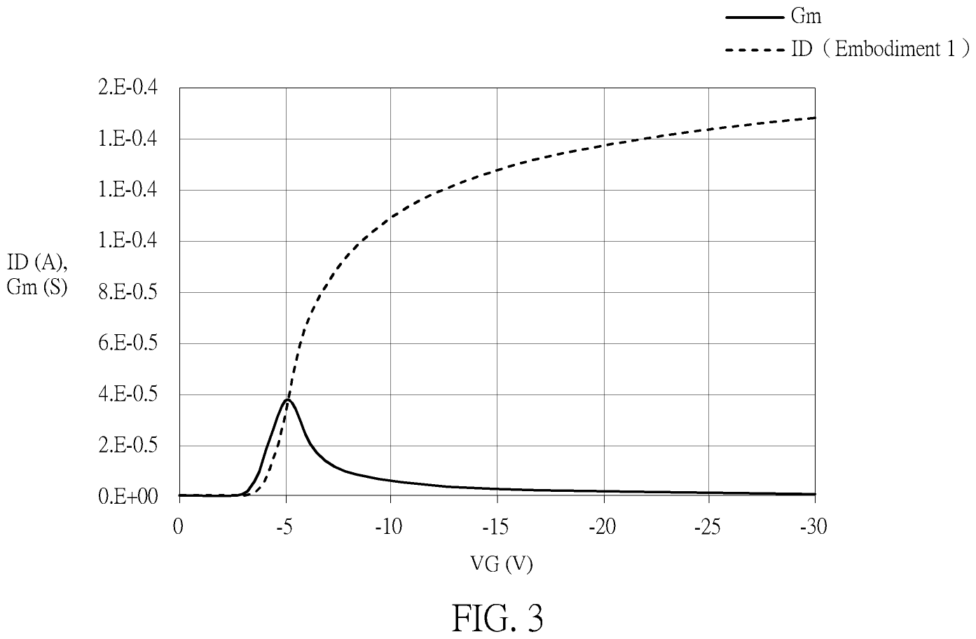

FIG. 3 shows characteristics of the drain current ID and the transconductance Gm versus the gate voltage VG of a high-voltage semiconductor device according to an Embodiment 1 of the present disclosure. In FIG. 3, the horizontal axis is the gate voltage VG with a unit of volts (V). The vertical axis shows the drain current ID with a unit of amperes (A). The vertical axis also shows the transconductance Gm, which is the ratio of the drain current ID to the gate voltage VG, with a unit of Siemens(S). The Embodiment 1 is the high-voltage semiconductor device 100 of FIG. 1, where the length of the isolation region 121 is 82 micrometers (μm). It is known from FIG. 3, when a higher negative gate voltage VG is applied to the high-voltage semiconductor device of the embodiment of the present disclosure, the drain current ID is increased accordingly, and the transconductance Gm is reversed at the gate voltage VG of −5V. It means that the high-voltage semiconductor device of the embodiment of the present disclosure has the operating characteristics of a PMOS FET.

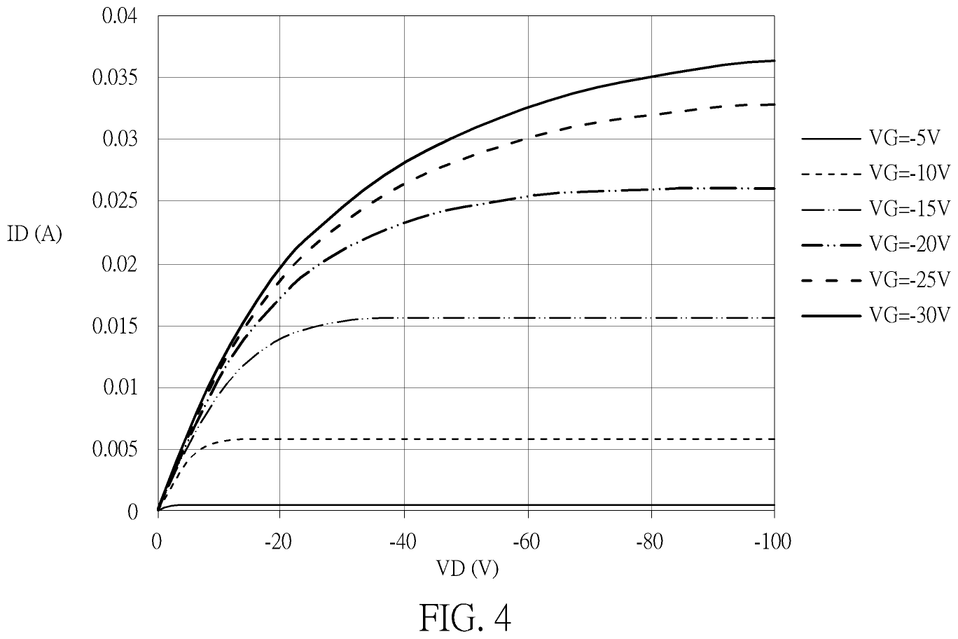

FIG. 4 shows characteristics of the drain current ID changing with the drain voltage VD of a high-voltage semiconductor device according to an embodiment of the present disclosure under the conditions of applying different gate voltages VG. In FIG. 4, the horizontal axis is the drain voltage VD with a unit of volts (V). The vertical axis is the drain current ID with a unit of amperes (A). It is known from FIG. 4, when a higher negative gate voltage VG is applied to the high-voltage semiconductor device of the embodiment of the present disclosure, the drain current ID is higher under the same drain voltage VD. It means that the high-voltage semiconductor device of the embodiment of the present disclosure has good operating characteristics of a PMOS FET.

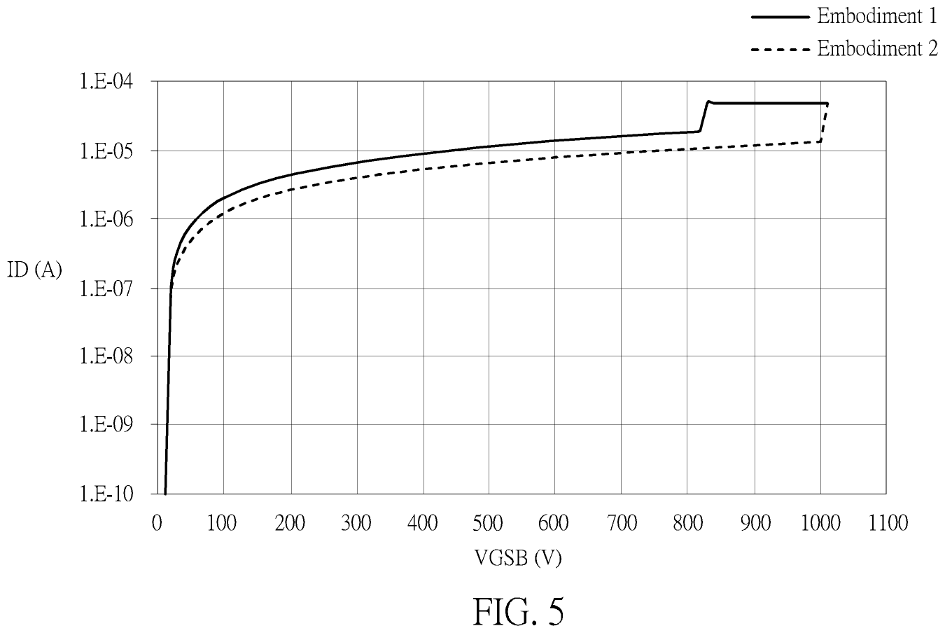

FIG. 5 shows characteristics of the drain current ID versus the gate-to-source voltage difference VGSB of two high-voltage semiconductor devices according to some embodiments of the present disclosure. In FIG. 5, the horizontal axis is the absolute value of the gate-to-source voltage difference VGSB with a unit of volts (V). The vertical axis is the drain current ID with a unit of amperes (A). The Embodiment 1 is the high-voltage semiconductor device 100 of FIG. 1, where the length of the isolation region 121 is 82 μm. The Embodiment 2 is the high-voltage semiconductor device 100 of FIG. 1, where the length of the isolation region 121 is 120 μm. It is known from FIG. 5, in the high-voltage semiconductor devices of the embodiments of the present disclosure, when the gate-to-source voltage difference VGSB is increased, the drain current ID is increased sharply at first and then is increased slow down. The off-state breakdown voltage (BVoff) of the high-voltage semiconductor device of the Embodiment 1 is about 800V. The off-state breakdown voltage (BVoff) of the high-voltage semiconductor device of the Embodiment 2 is about 1000V. It means that the high-voltage semiconductor devices of some embodiments of the present disclosure withstand ultra-high voltages of more than negative 700V. Moreover, increasing the length of the isolation region 121 of the high-voltage semiconductor devices 100 further increases the breakdown voltage.

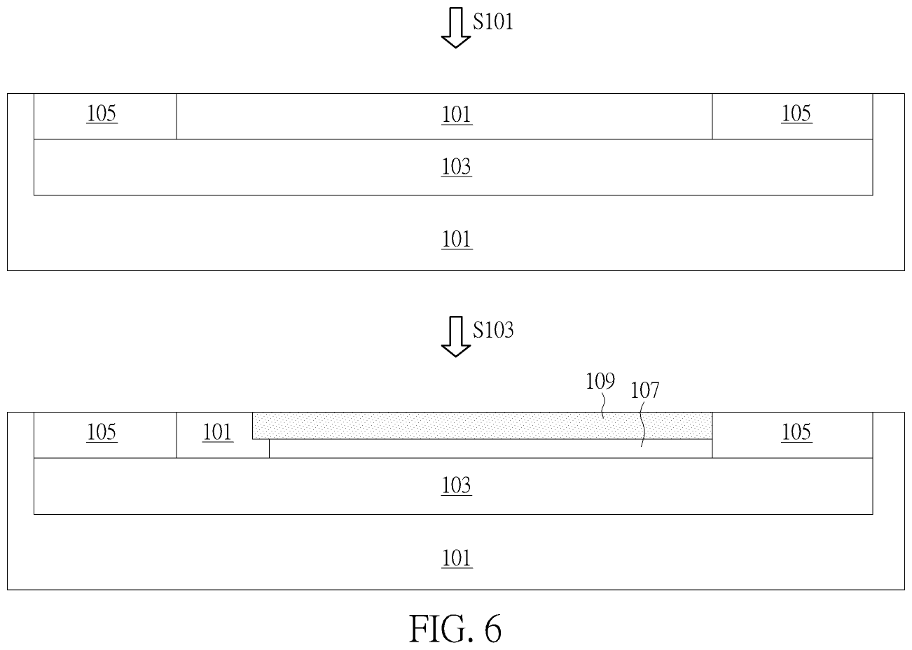

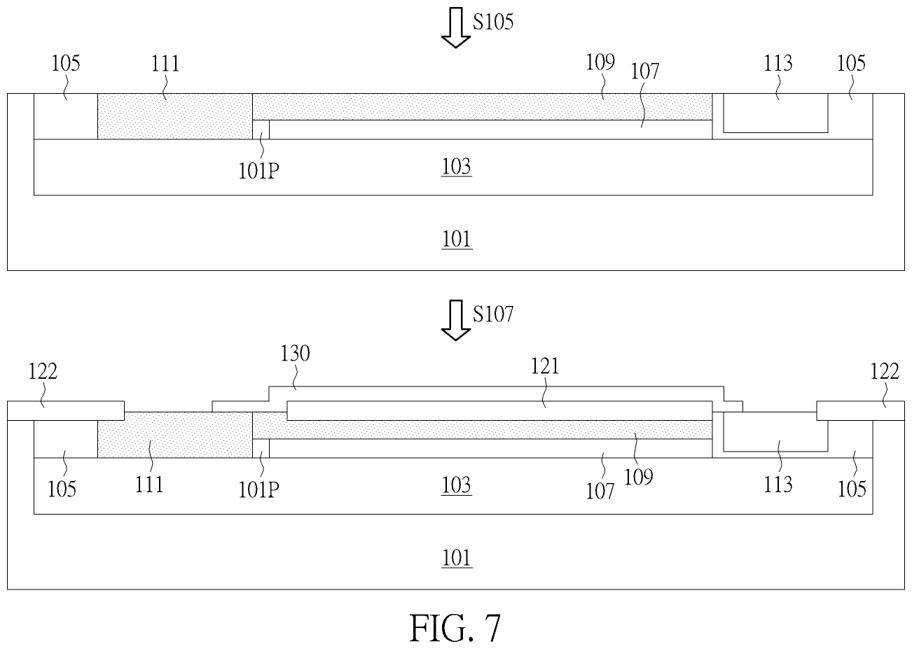

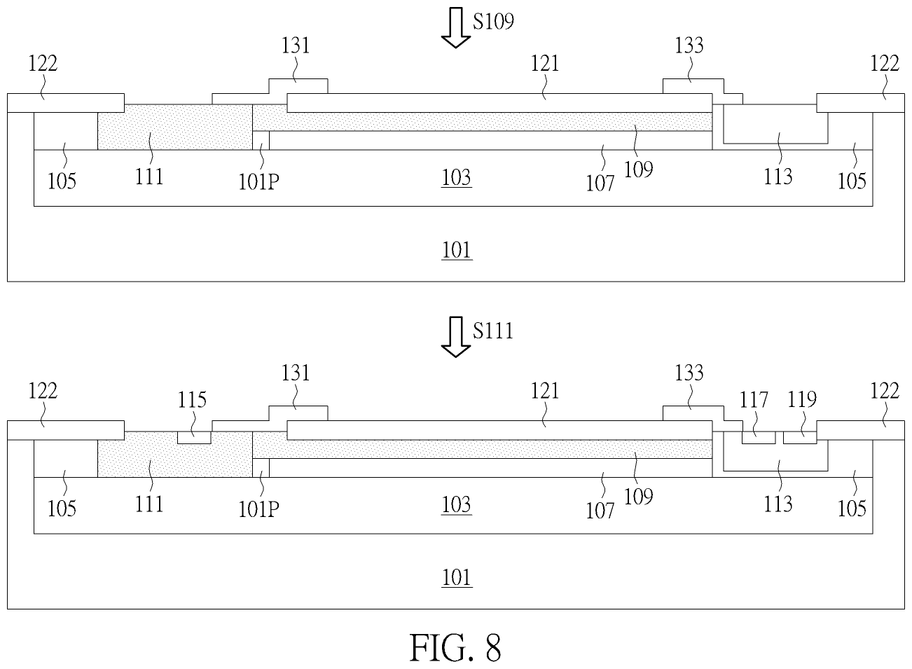

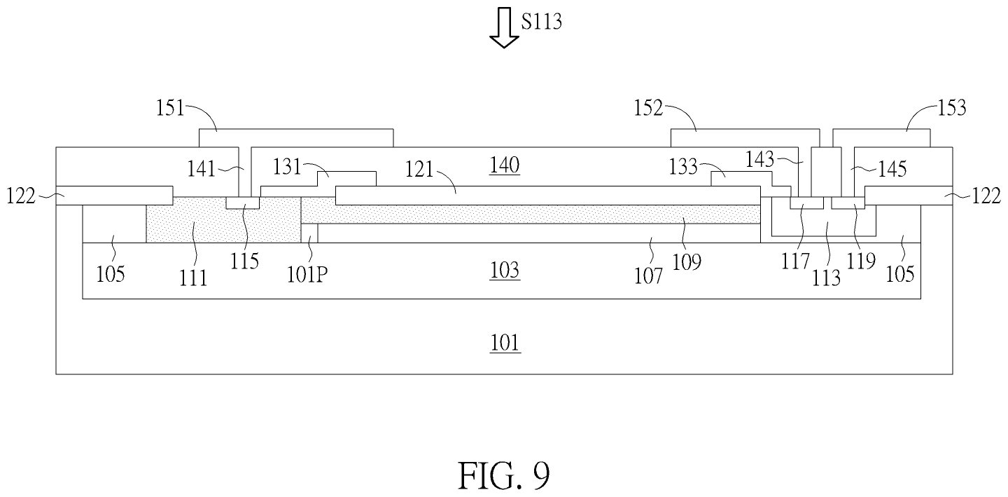

FIG. 6, FIG. 7, FIG. 8 and FIG. 9 are schematic cross-sectional views of some stages of a method of fabricating a high-voltage semiconductor device according to an embodiment of the present disclosure. Referring to FIG. 6, in step S101, firstly, a substrate 101 is provided, for example, a p-type semiconductor substrate. The composition of the substrate 101 may be silicon (Si), silicon carbide (SiC) or other suitable semiconductor materials. Then, a deep well region 103 is formed in the substrate 101 by using an ion implantation process and a mask to implant n-type dopants into the substrate 101. Next, a third well region 105 is formed on the deep well region 103 by using an ion implantation process and another mask to implant n-type dopants into the substrate 101. When viewed from top, the third well region 105 has an annular shape. In some embodiments, the third well region 105 and the deep well region 103 may have the same doping concentration, for example, about 1E15 cm⁻³ to about 1E16 cm⁻³.

Still referring to FIG. 6, in step S103, in one embodiment, a second doped top layer 107 is formed in the substrate 101 by using an ion implantation process and a mask to implant n-type dopants into the substrate 101. The second doped top layer 107 is formed on the deep well region 103, and located in the area surrounded by the third well region 105. Then, a first doped top layer 109 is formed by using another ion implantation process and another mask to implant p-type dopants into the substrate 101. The first doped top layer 109 is located directly above the second doped top layer 107. The left side of the first doped top layer 109 protrudes outward from the left side of the second doped top layer 107. The right side of the first doped top layer 109 and the right side of the second doped top layer 107 may be vertically aligned with each other and both in contact with one side surface of the third well region 105. In some embodiments, the second doped top layer 107 and the first doped top layer 109 may have the same doping concentration, for example, about 5E16 cm⁻³ to about 1E17 cm⁻³. In another embodiment, the second doped top layer 107 and the first doped top layer 109 may be formed by using the same mask, so that two sides of the second doped top layer 107 and two sides of the first doped top layer 109 are vertically aligned with each other, as shown in FIG. 2.

Next, referring to FIG. 7, in step S105, a first well region 111 is formed by using an ion implantation process and a mask to implant p-type dopants into both the substrate 101 and the third well region 105 located on the left side of the second doped top layer 107 and the first doped top layer 109. Moreover, a second well region 113 is formed by using another ion implantation process and another mask to implant n-type dopants into both the substrate 101 and the third well region 105 located on the right side of the second doped top layer 107 and the first doped top layer 109. In some embodiments, the doping concentration of the first well region 111 is higher than the doping concentration of the first doped top layer 109. The doping concentration of the first well region 111 is, for example, about 5E17 cm⁻³ to about 1E18 cm⁻³. The doping concentration of the second well region 113 is higher than the doping concentration of the third well region 105. The doping concentration of the second well region 113 is, for example, about 5E17 cm⁻³ to about 1E18 cm⁻³.

Still referring to FIG. 7, in step S107, isolation regions 121 and 122 are formed on the surface of the substrate 101. In one embodiment, the isolation regions 121 and 122 are formed by using a wet oxidation process and a mask, where H₂O vapor is introduced for oxidation to grow field oxide layers as the isolation regions 121 and 122. In another embodiment, the isolation regions 121 and 122 are formed by etching and deposition processes, where the substrate 101 is etched to form trenches, and then the trenches are filled up with a dielectric material to form shallow trench isolation structures as the isolation regions 121 and 122. Next, in step S107, in one embodiment, a polysilicon layer 130 is formed on the isolation region 121 by a deposition process. The polysilicon layer 130 is extended laterally from the isolation region 121 onto the first well region 111 and the second well region 113.

Then, referring to FIG. 8, in step S109, the polysilicon layer 130 is patterned by photolithography and etching processes to form a field plate 131 and a gate electrode 133 laterally separated from each other. The field plate 131 is extended laterally from the isolation region 121 onto the first well region 111. The gate electrode 133 is extended laterally from the isolation region 121 onto the second well region 113.

Still referring to FIG. 8, in step S111, a drain contact region 115 is formed by using an ion implantation process and a mask to implant p-type dopants into the first well region 111. Also, a source contact region 117 is simultaneously formed by using the ion implantation process and the mask to implant the p-type dopants into the second well region 113. In some embodiments, the drain contact region 115 and the source contact region 117 are, for example, p-type heavily doped regions, and have the same doping concentration, for example, about 5E18 cm⁻³ to about 5E19 cm⁻³. Then, a bulk contact region 119 is formed by using another ion implantation process and another mask to implant n-type dopants into the second well region 113. The bulk contact region 119 is laterally separated from the source contact region 117. In some embodiments, the doping concentration of the bulk contact region 119 is, for example, about 5E18 cm⁻³ to about 5E19 cm⁻³.

Next, referring to FIG. 9, in step S113, an interlayer dielectric (ILD) layer 140 is formed on the surface of the substrate 101 by a deposition process. The ILD layer 140 fully covers the isolation regions 121 and 122, the first well region 111, the second well region 113, the field plate 131 and the gate electrode 133. Then, a drain contact 141, a source contact 143 and a bulk contact 145 are formed in the ILD layer 140 by etching and deposition processes. The drain contact 141, the source contact 143 and the bulk contact 145 are electrically connected to the drain contact region 115, the source contact region 117 and the bulk contact region 119, respectively. Next, a first metal layer is formed on the ILD layer 140 by a deposition process, and then the first metal layer is patterned by photolithography and etching processes to form a drain electrode 151, a source electrode 152 and a bulk electrode 153 those are electrically connected to the drain contact 141, the source contact 143 and the bulk contact 145, respectively. Afterwards, referring to FIG. 1, an interconnect structure 180 is formed on the ILD layer 140, the drain electrode 151, the source electrode 152 and the bulk electrode 153 to complete the high-voltage semiconductor device 100.

According to some embodiments of the present disclosure, a p-type doped top layer and a p-type well region of a source region in an n-type MOSFET structure are used as the drain region of the p-type MOSFET of the high-voltage semiconductor devices. The p-type doped top layer and the p-type well region construct a continuous p-type structure, thereby withstanding ultra-high voltages of more than negative 700V. Therefore, the high-voltage semiconductor devices of the embodiments of the present disclosure are suitable for various applications under ultra-high operating voltages. For example, the high-voltage semiconductor devices may be used as an anti-shoot-through protection device in a bridge circuit to detect the highest potential signal of a high-side circuit, and withstand ultra-high voltages of more than negative 700V. Moreover, the fabrication of the high-voltage semiconductor devices of the embodiments of the present disclosure is compatible with the process flow of fabricating an n-type MOSFET without additional photomask, thereby saving the manufacturing cost of the high-voltage semiconductor devices and maintaining a smaller chip area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high-voltage semiconductor device, comprising:
a substrate, having a first conductivity type;
a first well region, having the first conductivity type and disposed in the substrate;
a second well region, having a second conductivity type and disposed in the substrate;
a first doped top layer, having the first conductivity type and disposed between the first well region and the second well region;
a drain contact region, disposed in the first well region;
a source contact region, disposed in the second well region;
an isolation region, disposed on the first doped top layer;
a gate electrode, disposed on the isolation region and extended laterally onto the second well region; and
a field plate, disposed on the isolation region and extended laterally onto the first well region.

2. The high-voltage semiconductor device of claim 1, wherein the first conductivity type is a p-type and the second conductivity type is an n-type.

3. The high-voltage semiconductor device of claim 1, wherein the first doped top layer is in direct contact with one side surface of the first well region, and the first well region and the first doped top layer construct a continuous structure having the first conductivity type to be a drain region.

4. The high-voltage semiconductor device of claim 1, wherein a doping concentration of the first well region is higher than a doping concentration of the first doped top layer.

5. The high-voltage semiconductor device of claim 1, further comprising a second doped top layer having the second conductivity type and disposed directly below the first doped top layer, wherein the second doped top layer is laterally separated from the first well region.

6. The high-voltage semiconductor device of claim 5, wherein a top surface of the second doped top layer is in direct contact with a bottom surface of the first doped top layer.

7. The high-voltage semiconductor device of claim 5, wherein a portion of the substrate is located between the first well region and the second doped top layer.

8. The high-voltage semiconductor device of claim 5, wherein a doping concentration of the second doped top layer is the same as a doping concentration of the first doped top layer.

9. The high-voltage semiconductor device of claim 5, wherein a side of the second doped top layer is vertically aligned with a side of the first doped top layer, a portion of the substrate is located between the first well region and the side of the first doped top layer, and the portion of the substrate is located between the first well region and the side of the second doped top layer.

10. The high-voltage semiconductor device of claim 9, wherein the first well region, the portion of the substrate and the first doped top layer construct a continuous structure having the first conductivity type to be a drain region.

11. The high-voltage semiconductor device of claim 5, further comprising:
a deep well region, having the second conductivity type and disposed directly below the first well region, the second doped top layer and the second well region; and
a third well region, having the second conductivity type, disposed on the deep well region, and surrounding the first well region, the first doped top layer, the second doped top layer and the second well region.

12. The high-voltage semiconductor device of claim 11, wherein a bottom surface of the first well region is in direct contact with a top surface of the deep well region, and the second doped top layer is in direct contact with the top surface of the deep well region.

13. The high-voltage semiconductor device of claim 11, wherein a side of the second doped top layer is vertically aligned with a side of the first doped top layer, a portion of the third well region is located between the second well region and the side of the first doped top layer, and the portion of the third well region is located between the second well region and the side of the second doped top layer.

14. The high-voltage semiconductor device of claim 11, wherein the second well region is located in the third well region, and a doping concentration of the second well region is higher than a doping concentration of the third well region.

15. The high-voltage semiconductor device of claim 11, wherein a doping concentration of the third well region is the same as a doping concentration of the deep well region.

16. The high-voltage semiconductor device of claim 1, further comprising a bulk contact region having the second conductivity type, disposed in the second well region and laterally separated from the source contact region.

17. The high-voltage semiconductor device of claim 16, further comprising:
a source electrode, electrically connected to the source contact region;
a bulk electrode, electrically connected to the bulk contact region;
a drain electrode, electrically connected to the drain contact region; and
an interconnect structure, comprising a plurality of metal layers disposed above the source electrode, the bulk electrode and the drain electrode, wherein the plurality of metal layers comprises a first portion, a second portion and a third portion laterally separated from each other and electrically connected to the drain electrode, the source electrode and the bulk electrode, respectively, the first portion comprises a plurality of drain field plates, and the second portion comprises a plurality of source field plates.

18. The high-voltage semiconductor device of claim 17, wherein each of vertical projection areas of the plurality of drain field plates covers and is larger than a vertical projection area of the field plate.

19. The high-voltage semiconductor device of claim 17, wherein each of vertical projection areas of the plurality of source field plates covers and is larger than a vertical projection area of the gate electrode.

20. The high-voltage semiconductor device of claim 1, wherein the field plate and the gate electrode are two laterally separated portions of a polysilicon layer.
